(19) United States
(12) Patent Application Publication
(10) Pub. No.: US 2019/0182996 A1
(43) Pub. Date: Jun. 13, 2019

(54) MANUFACTURING CONTROLLED DISPERSION HIGH CONCENTRATION NANOPARTICLES IN NANOCOMPOSITES

(71) Applicant: North Carolina Agricultural and Technical State University, Greensboro, NC (US)

(72) Inventors: Ajit D. Kelkar, Greensboro, NC (US); Nasim Abuali Galehdari, Greensboro, NC (US)

(21) Appl. No.: 16/211,987

(22) Filed: Dec. 6, 2018

Related U.S. Application Data
(60) Provisional application No. 62/595,268, filed on Dec. 6, 2017.

(51) Int. Cl. H05K 9/00; B29C 39/38; B29C 39/00

(52) U.S. Cl. CPC H05K 9/0083; B29C 70/443; B29C 39/003; B29C 39/38

(57) ABSTRACT

Nanocomposites comprising a polymer matrix having a controlled dispersion of nanoparticles at high concentrations are described. The nanoparticles can be materials that absorb radiation. Thus, the nanocomposites can be of use in radiation shielding. Also described are methods of preparing the nanocomposites and multifunctional structures, such as sandwich panels, comprising the nanocomposites.

### RELATED APPLICATIONS

The presently disclosed subject matter claims the benefit of U.S. Provisional Patent Application Ser. No. 62/595,268, filed Dec. 6, 2017; the disclosure of which is incorporated herein by reference in its entirety.

### TECHNICAL FIELD

The presently disclosed subject matter relates to nanocomposites comprising a controlled dispersion of nanoparticles in polymer matrices and methods for making the nanocomposites. The nanoparticles can include nanoparticles that absorb and/or disperse radiation such that the nanocomposites can be used in radiation shielding.

### BACKGROUND

Radiation shielding is an important consideration in a number industries, such as aerospace and nuclear power plant operation, as well as in nuclear spill clean-ups and in hospitals. While the quality of radiation protection has steadily increased over the years, there are still challenges to providing a cost effective shielding structure that provides up to 100% shielding from different types of radiation, including secondary radiation, e.g. neutron radiation. Such structures can protect not only humans, but also materials and electronics.

There remains a need for additional materials, such as mutlifunctional structures, with improved radiation absorption efficiency, particularly in combination with robust mechanical integrity. There is also a need for methods of making such materials that is simple and easily tailorable. For example, there is a need for methods for the controlled incorporation of a high concentration of radiation-absorbing nanoparticles into a thick polymeric composite with minimal sedimentation/agglomeration of the nanoparticles.

### SUMMARY

In some embodiments, the presently disclosed subject matter provides a method of preparing a nanocomposite comprising: (a) depositing a layer comprising a resin mixture, wherein the resin mixture comprises a thermoset polymer resin and a pre-determined concentration of nanoparticles; (b) curing the layer until the thermoset polymer resin reaches its gel point, thereby providing a thermoset polymer layer having a homogenous distribution of nanoparticles of the pre-determined concentration embedded therein; and (c) repeating the deposition/curing steps (a) and (b) to provide a nanocomposite comprising a plurality of thermoset polymer layers, wherein each thermoset polymer layer contains a separately defined concentration of nanoparticles, and wherein the nanocomposite has a thickness of at least about 0.5 centimeters (cm) and a controlled dispersion of nanoparticles. In some embodiments, the thermoset polymer resin is an epoxy resin.

In some embodiments, the nanoparticles in each thermoset polymer layer are independently selected from the group comprising boron nanoparticles, boron carbide nanoparticles, gadolinium nanoparticles, nickel nanoparticles, carbon nanotubes, and boron nitride nanotubes. In some embodiments, the nanoparticles in each of the plurality of thermoset polymer layers have the same chemical composition and/or the same size. In some embodiments, the nanoparticles in each of the plurality of thermoset polymer layers have a different chemical composition and/or a different size.

In some embodiments, the separately defined concentration of nanoparticles in at least one of the plurality of thermoset polymer layers is more than about 10 weight percent (wt %). In some embodiments, the separately defined concentration of nanoparticles in each of the plurality of thermoset polymer layers is between about 2 wt % and about 10 wt %.

In some embodiments, the nanocomposite is at least about 1.0 cm thick. In some embodiments, the nanocomposite has improved structural strength compared to a nanocomposite of the same thickness and containing the same weight percentage of nanoparticles prepared using a different method, optionally wherein the different method comprises depositing and curing a single layer of a mixture comprising a thermoset polymer resin and nanoparticles.

In some embodiments, the nanocomposite has improved conductivity compared to a nanocomposite of the same thickness and containing the same weight percentage of nanoparticles prepared using a different method, optionally wherein the different method comprises depositing and curing a single layer of a mixture comprising a thermoset polymer resin and nanoparticles. In some embodiments, said improved conductivity is an electrical conductivity and/or a thermal conductivity. In some embodiments, the nanocomposite has a shielding efficiency of at least about 65%.

In some embodiments, the resin mixture is free of an additive to improve the compatibility of the nanoparticles and the resin. In some embodiments, the nanoparticles are free of surface modification and/or chemical derivatization. In some embodiments, the presently disclosed subject matter provides a nanocomposite produced by the method comprising: (a) depositing a layer comprising a resin mixture, wherein the resin mixture comprises a thermoset polymer resin and a pre-determined concentration of nanoparticles; (b) curing the layer until the thermoset polymer resin reaches its gel point, thereby providing a thermoset polymer layer having a homogenous distribution of nanoparticles of the pre-determined concentration embedded therein; and (c) repeating the deposition/curing steps (a) and (b) to provide a nanocomposite comprising a plurality of thermoset polymer layers, wherein each thermoset polymer layer contains a separately defined concentration of nanoparticles, and wherein the nanocomposite has a thickness of at least about 0.5 centimeters (cm) and a controlled dispersion of nanoparticles.

In some embodiments, the presently disclosed subject matter provide a multifunctional structure comprising a nanocomposite produced by the method comprising: (a) depositing a layer comprising a resin mixture, wherein the resin mixture comprises a thermoset polymer resin and a pre-determined concentration of nanoparticles; (b) curing the layer until the thermoset polymer resin reaches its gel point, thereby providing a thermoset polymer layer having a homogenous distribution of nanoparticles of the pre-determined concentration embedded therein; and (c) repeating the deposition/curing steps (a) and (b) to provide a nanocomposite comprising a plurality of thermoset polymer layers, wherein each thermoset polymer layer contains a separately defined concentration of nanoparticles, and wherein the nanocomposite has a thickness of at least about 0.5 centimeters (cm) and a controlled dispersion of nanoparticles, optionally wherein said multifunctional structure comprises a sandwich panel comprising two face sheets and the nanocomposite, wherein each of the two face sheets is laminated to one side of the nanocomposite.

In some embodiments, the presently disclosed subject matter provides a nanocomposite comprising a thermoset polymer matrix and having a thickness of about 0.5 centimeter of more, wherein the nanocomposite comprises a controlled dispersion of nanoparticles distributed throughout the matrix. In some embodiments, the nanocomposite has a thickness of about 1.0 cm or more.

In some embodiments, the nanocomposite has a concentration of nanoparticles of greater than about 10 wt %. In some embodiments, the nanoparticles are independently selected from the group comprising boron nanoparticles, boron carbide nanoparticles, gadolinium nanoparticles, nickel nanoparticles, carbon nanotubes, and boron nitride nanotubes. In some embodiments, the nanoparticles are free of surface modification and/or chemical derivatization.

In some embodiments, the nanocomposite comprises a plurality of layers, each of which comprises a homogenous distribution of nanoparticles, wherein the concentration of nanoparticles in at least one layer is different from the concentration of nanoparticles in at least one of the other layers. In some embodiments, the nanocomposite comprises a plurality of layers, each of which comprises a homogenous dispersion of nanoparticles, wherein the chemical composition and/or size of the nanoparticles in at least one of the layers is different from the chemical composition and/or size of nanoparticles in at least one of the other layers.

In some embodiments, the presently disclosed subject matter provides a multifunctional structure comprising a nanocomposite comprising a thermoset polymer matrix and having a thickness of about 0.5 centimeter of more, wherein the nanocomposite comprises a controlled dispersion of nanoparticles distributed throughout the matrix. In some embodiments, the multifunctional structure comprises a sandwich panel, wherein said sandwich panel comprises two face sheets and the nanocomposite, and wherein each of the two face sheets is laminated to one side of the nanocomposite, wherein each of the two face sheets comprises a woven polymer, optionally wherein the woven polymer comprises ultrahigh molecular weight polyethylene fibers (UHMWPE).

Accordingly, it is an object of the presently disclosed subject matter to provide a method for preparing nanocomposites and multifunctional structures comprising the nanocomposites, as well as to provide the nanocomposites and multifunctional structures, themselves.

An object of the presently disclosed subject matter having been stated hereinabove, and which is achieved in whole or in part by the presently disclosed subject matter, other objects will become evident as the description proceeds when taken in connection with the accompanying drawings as best described herein.

### BRIEF DESCRIPTION OF THE DRAWINGS

FIG. 1 a schematic view of a cross-section of a nanocomposite comprising a controlled gradient dispersion of nanoparticles in a polymer matrix.

FIG. 2 is a schematic view of a cross-section of a multifunctional structure comprising the nanocomposite of FIG. 1.

FIG. 3 is a flow diagram of a method of preparing a nanocomposite of the presently disclosed subject matter.

FIG. 4A is a pair of microscope images showing sedimentation of nanoparticles in the bottom of a nanocomposite comprising nanoparticles in a polymer matrix prepared in a single layer casting. The image on the left is at 5 times magnification, while the image on the right is at 100 times magnification.

FIG. 4B is a pair of microscope images showing lack of sedimentation of nanoparticles in the bottom of a nanocomposite comprising nanoparticles in a polymer matrix prepared by casting three separate layers according to the method of the presently disclosed subject matter. The image on the left is at 5 times magnification, while the image on the right is at 100 times magnification.

FIG. 5 is a schematic of a nanocomposite of the presently disclosed subject matter undergoing a flexural strength measurement with a load directed at point B. The sample is under compression at point B and under tension at point A.

FIG. 6A is a graph of theoretical neutron absorption of nanocomposites of the presently disclosed subject matter as a function of nanoparticle loading (in weight percent (wt %)) as exemplified by epoxy nanocomposites with boron nitride nanoparticles (Epoxy/BC, triangles) or epoxy nanocomposites with boron nanopowder (Epoxy/Boron Nanopowder, squares). The theoretical neutron absorption is described as the ratio I/I₀ of the decrease in neutron flux, where I is a measure of neutrons passing through the nanocomposite and I₀ is a measure of neutrons originally directed to the nanocomposite.

FIG. 6B is a bar graph of the attenuation efficiency for nanocomposites of the presently disclosed subject matter having 0.5 cm thickness and prepared from: neat epoxy (control with no nanoparticles); epoxy having 3 weight percent (wt %) gadolinium nanoparticles (Epoxy/Gd 3%); epoxy having 3 wt % boron carbide nanoparticles (Epoxy/BC 3%); or epoxy having 3 wt % boron nanopowder (Epoxy/Boron Nanopowder 3%).

### DETAILED DESCRIPTION

The presently disclosed subject matter will now be described more fully. The presently disclosed subject matter can, however, be embodied in different forms and should not be construed as limited to the embodiments set forth herein below and in the accompanying Examples. For example, features illustrated with respect to one embodiment can be incorporated into other embodiments, and features illustrated with respect to a particular embodiment can be deleted from that embodiment. Thus, one or more of the method steps included in a particular method described herein can, in other embodiments, be omitted and/or performed independently. In addition, numerous variations and additions to the embodiments suggested herein, which do not depart from the instant invention, will be apparent to those skilled in the art in light of the instant disclosure. Hence, the following description is intended to illustrate some particular embodiments of the invention, and not to exhaustively specify all permutations, combinations and variations thereof. It should therefore be appreciated that the present invention is not limited to the particular embodiments set forth herein. Rather, these particular embodiments are provided so that this disclosure will more clearly convey the full scope of the invention to those skilled in the art.

All references listed herein, including but not limited to all patents, patent applications and publications thereof, and scientific journal articles, are incorporated herein by reference in their entireties to the extent that they supplement, explain, provide a background for, or teach methodology, techniques, and/or compositions employed herein.

### I. Definitions

While the following terms are believed to be well understood by one of ordinary skill in the art, the following definitions are set forth to facilitate explanation of the presently disclosed subject matter.

Unless defined otherwise, all technical and scientific terms used herein have the same meaning as commonly understood to one of ordinary skill in the art to which the presently disclosed subject matter belongs. References to techniques employed herein are intended to refer to the techniques as commonly understood in the art, including variations on those techniques or substitutions of equivalent techniques that would be apparent to one of skill in the art.

Following long-standing patent law convention, the terms “a”, “an”, and “the” refer to “one or more” when used in this application, including the claims.

The term “and/or” when used in describing two or more items or conditions, refers to situations where all named items or conditions are present or applicable, or to situations wherein only one (or less than all) of the items or conditions is present or applicable.

The use of the term “or” in the claims is used to mean “and/or” unless explicitly indicated to refer to alternatives only or the alternatives are mutually exclusive, although the disclosure supports a definition that refers to only alternatives and “and/or.”

As used herein “another” can mean at least a second or more.

The term “comprising”, which is synonymous with “including,” “containing,” or “characterized by” is inclusive or open-ended and does not exclude additional, unrecited elements or method steps. “Comprising” is a term of art used in claim language which means that the named elements are essential, but other elements can be added and still form a construct within the scope of the claim.

As used herein, the phrase “consisting of” excludes any element, step, or ingredient not specified in the claim. When the phrase “consists of” appears in a clause of the body of a claim, rather than immediately following the preamble, it limits only the element set forth in that clause; other elements are not excluded from the claim as a whole.

As used herein, the phrase “consisting essentially of” limits the scope of a claim to the specified materials or steps, plus those that do not materially affect the basic and novel characteristic(s) of the claimed subject matter.

With respect to the terms “comprising”, “consisting of”, and “consisting essentially of”, where one of these three terms is used herein, the presently disclosed subject matter can include the use of either of the other two terms.

Unless otherwise indicated, all numbers expressing quantities of weight, mass, volume, time, activity, percentage (%), and so forth used in the specification and claims are to be understood as being modified in all instances by the term “about”. Accordingly, unless indicated to the contrary, the numerical parameters set forth in this specification and attached claims are approximations that can vary depending upon the desired properties sought to be obtained by the presently disclosed subject matter.

As used herein, the term “about”, when referring to a value is meant to encompass variations of in one example ±20% or ±10%, in another example ±5%, in another example ±1%, and in still another example ±0.1% from the specified amount, as such variations are appropriate to perform the disclosed methods.

“Radiation shielding,” or “shielding” as used herein refers to the protection of people and devices from the harmful effects of radiation, such as electron, proton, neutron, or electromagnetic radiation. Radiation includes but is not limited to Galactic Cosmic Radiation (GCR) and Solar Cosmic Radiation (SCR). While protection of humans is typically the first consideration for radiation shielding, the negative impact of radiation on materials and electronic are also of interest.

The terms “resin” and “polymer” as used herein generally refer to “thermoset resin” or “thermoset polymer,” respectively. The most frequently used thermosetting resins include, but are not limited to, polyesters, epoxies, phenolics, vinyl esters, polyurethanes, silicones, polyamides, and polyamide-imides.

As used herein, the term “nanoparticles” refers to particles having an average longest length or diameter that is less than about 1000 nm. Generally, nanoparticles are mostly spherical, but as disclosed herein, nanoparticles can also be cylindrical, such as nanotubes. Typically, nanoparticles have an average longest length of less than about 750 nm, less than about 500 nm, less than about 250 nm, less than about 100 nm, less than about 20 nm, less than about 25 nm, or even less than about 10 nm. Alternately, the nanoparticles can have an average longest length of between about 100 nm and 900 nm, between about 200 nm and 700 nm, between about 300 nm and 600 nm, between about 500 nm and 700 nm, between about 200 nm and 400 nm, or between about 40 nm and 200 nm. Alternately, nanoparticles have an average longest length of at least about 50 nm, at least about 100 nm, at least about 250 nm, at least about 300 nm, at least about 400 nm, at least about 500 nm, at least about 600 nm, at least about 700 nm, or at least about 800 nm. Typically, nanoparticles of the presently disclosed subject matter have radiation absorbing/dispersing properties, and can comprise, for instance, carbon nanotubes, boron nitride nanotubes, boron carbide, boron, gadolinium, nickel, and combinations thereof. The nanoparticles used in the methods disclosed herein are generally not modified, such as with surfactants or chemical derivativization, before or during incorporation into the polymer matrix.

As used herein, “dispersed” refers to distribution of nanoparticles within a polymer matrix. “Homogeneously dispersed,” “evenly dispersed,” or “uniformly dispersed” refers to a distribution wherein sedimentation and agglomeration are minimized, as generally reflected by robust compressive strength, tensile strength, or flexural strength or thermal, electrical and/or energy absorption/conductivity properties.

The term “controlled dispersion” as used herein refers to a homogenous dispersion of nanoparticles having a pre-determined nanoparticle concentration (or wt %) or a pre-determined nanoparticle concentration gradient or gradients Thus, composites comprising a “controlled dispersion” of nanoparticles can comprise a plurality of layers in which the concentration of homogenously dispersed nanoparticles can be the same or different from one or more of the other layers in the composite. In some embodiments, the concentration of nanoparticles increases or decreases in each adjacent layer of the composite going from one side of the composite to the other. In some embodiments, the concentration of nanoparticles can increase from one adjacent layer to the next and then decrease from one adjacent layer to the next going from one side of a composite to another. The pattern of concentration increase and decrease can be repeated one or more times in the plurality of layers. Thus, in some embodiments, the concentration of homogenously dispersed nanoparticles can change in a pulsatile pattern.

As used herein “sedimentation” refers to the settling of nanoparticles, typically in an aggregation or agglomeration. As used herein, an agglomerate or an aggregate is a mass consisting of particulate subunits formed via physical (van der Waals, hydrophobic) or electrostatic forces. The resulting structure is called an “agglomerate.”

The degree of nanoparticle sedimentation is influenced by both the density of the nanoparticles and the viscosity of the resin matrix. Less dense particles and/or highly viscous resins are less susceptible to settling of nanoparticles. Nanoparticles of greater density and/or less viscous resins are more susceptible to sedimentation in the final nanocomposite. The combination of less dense particles in resin(s) having lower viscosity can lead to sedimentation, as can higher density nanoparticles combined with more highly viscous resins. The methods disclosed herein can be used to reduce or eliminate sedimentation of a nanocomposite.

As used herein, “multifunctional structures” are materials with both load-bearing properties and non-load-bearing properties, such as thermal/electrical conductivity, wave absorption properties, radiation/electromagnetic interface shielding, etc. A “sandwich panel” is a common structure of multifunctional materials. A sandwich structure is a laminated composite which comprises two thin, rigid and high strength face sheets bonded to a thick, lightweight core comprising a cured resin or nanocomposite of the presently disclosed subject matter. In some embodiments, the face sheets comprise woven polymer, such as for example, ultrahigh molecular weight polyethylene fibers (UHMWPE), which have excellent mechanical and shielding properties, in part due to their high hydrogen content. Alternatively, the woven polymer can be a polyester or an aramid. Sandwich structures can be symmetric, wherein the face sheets comprise the same material and fiber thickness and have the same thickness, or asymmetric, wherein the face sheets vary in one or more of thickness, materials, and fiber orientation.

As used herein “nanocomposite” refers to a polymer matrix comprising a dispersion of nanoparticles embedded throughout the matrix. When prepared according to the methods disclosed herein, nanocomposites typically contain a controlled dispersion of nanoparticles, either a gradient distribution or a constant homogenous distribution of one or more different nanoparticles within the cured polymer matrix.

As used herein a “hybrid nanocomposite” refers to a cured polymer matrix comprising at least two controlled dispersions of nanoparticles. In some embodiments, one nanoparticle dispersion is substantially constant throughout some or all of the matrix and the other nanoparticle dispersion is a controlled gradient throughout some or all of the matrix.

As used herein, a “gel point” of resin (or resin mixture) refers to the combination of time and temperature at which the resin is no longer a liquid and does not have the ability to flow, that is when the material changes in an irreversible way from a viscous liquid state to a solid state during the curing process. As is familiar to those of ordinary skill in the art, the gel point can be determined a variety of ways and is generally defined as the point in dynamic rheology measurement where tan δ (wherein δ is the phase lag between stress and strain in viscoelastic materials; tan δ=G′/G″) becomes frequency independent or when the G′=G″ crossover occurs (where G′ is storage modulus, generally describing the elastic properties; G″ is the loss modulus generally describing the viscous properties of viscoelastic materials). The gel point can also be calculated based on the known chemistry of the reactants. For example, in an epoxy-amine system gelation generally occurs at about 50% conversion, that is, when 50% of the polymer is cured. Beyond the gel point, the on-going chemical reactions increase the density of cross-linking, thereby curing the polymer.

As used herein, “specific gravity” or “relative density” refers to the ratio of the mass in air of a unit volume of the impermeable portion of the material at room temperature to the mass in air of equal density of an equal volume of gas-free distilled water at the same temperature.

### II. Methods of Making Nanocomposites with Uniformly Dispersed Nanoparticles

Nanocomposites, materials comprising nanoparticles held in polymer matrices, can be used to prepare materials having radiation absorbing/dispersing properties. Nanoparticles for use in such composites include, but are not limited to, boron nitride nanotubes, carbon nanotubes, boron carbide, boron, nickel, and gadolinium.

Controlled loading of significant amounts of nanoparticles into polymeric matrices has been difficult to achieve and the properties of the resulting nanocomposites are directly affected by poor dispersion of the nanoparticles—poor dispersion can significantly degrade the performance of the nanocomposite. In particular, it is difficult to achieve controlled particle dispersion through a polymeric matrix thicker than 0.5 cm. One commonly observed problem is settling, or sedimentation, of nanoparticles due to either gravity or the tendency of nanoparticles to aggregate during the fabrication process. Settling of nanoparticles leads to very poor dispersion and substantially limits the effective maximum loading of nanoparticles in a mechanically robust material. Aggregated/settled particles decrease the mechanical strength of the material at least in part because the regions of aggregation act as stress concentration region(s) and are the point(s) of failure of the material under load. Sedimentation/aggregation of nanoparticles can also introduce voids into the matrix, which act as preferential sites for crack initiation and failure.

Strategies to incorporate significant concentrations of nanoparticles into a polymer matrix have not yet been successful in the preparation of structurally robust nanocomposites for use in multifunctional materials. Such efforts have included modifying the nanoparticles, either chemically or via surfactants, and/or using in situ polymerization of polymeric starting material. Yet only limited incorporation of nanoparticles, for example, in thin matrix layers, typically less than 0.25 cm, have been shown to be successful.

The presently disclosed subject matter provides, in some embodiments, a method for providing a tailored shielding structure comprising a thick nanocomposite comprising a polymer matrix having a controlled distribution of nanoparticles, wherein the structure has both shielding efficiency and robust mechanical integrity. In particular, according to some embodiments of the presently disclosed subject matter, nanocomposites can be provided with controlled incorporation of a high concentration of nanoparticles (e.g., greater than about 10 wt % in at least one portion of the nanocomposite) with minimal sedimentation in a thick (e.g., greater than about 0.5 cm thick) polymeric composite.

Accordingly, in some embodiments, the presently disclosed subject matter provides a method of preparing a nanocomposite comprising: (a) depositing a layer comprising a resin mixture, wherein the resin mixture comprises a thermoset polymer resin and a pre-determined concentration of nanoparticles; (b) curing the layer until the thermoset polymer resin reaches its gel point, thereby providing a thermoset polymer layer having a homogenous dispersion of nanoparticles of the pre-determined concentration embedded therein; and (c) repeating steps (a) and (b) to provide a nanocomposite comprising a plurality of thermoset polymer layers, wherein each thermoset polymer layer contains a separately defined concentration of nanoparticles, and wherein the nanocomposite has a thickness of at least about 0.5 cm and a controlled dispersion of nanoparticles. Without being bound by any one theory, it is believed that upon casting a ‘new’ resin layer on top of a resin layer already at its gel point, a chemical reaction occurs between the reactive groups of the ‘new’ and ‘gelled’ layers, thereby ensuring adhesion between the sequentially deposited resin layers. Using appropriate gel time(s), a nanocomposite of thickness greater than 0.5 cm, greater than 0.75 cm, greater than 1 cm, greater than 1.5 cm, greater than 5 cm, greater than 7.5 cm, greater than 10 cm, greater than 15 cm, or greater than 20 cm can be prepared by depositing any number of thin (e.g. less than 0.5 cm) layers of resin containing nanoparticles thereby yielding a thick nanocomposite that does not suffer from sedimentation/agglomeration of those nanoparticles. Thus, the methods disclosed herein yield a thick nanocomposite prepared from one or more polymer mix(es) comprising at least about 5 wt % dispersed nanoparticles, alternately at least about 10 wt %, at least about 12.5 wt %, at least about 15 wt %, at least about 20 wt %, or at least about 30 wt % nanoparticles dispersed in the polymer mix.

In some embodiments, the method further comprises a step (d) comprising curing the composite after the final layer of thermoset polymer is deposited. In some embodiments, the curing of step (d) comprising heating the nanocomposite to a temperature at least about 10 degrees above a temperature used for the curing of step (b) for a period of time. In some embodiments, the temperature of the curing of step (d) is about 10, 15, 20, 25, 30, 35, 40, 45, 50, 55, 60, 65, 70, or about 75° C. above a temperature used in the curing of step (b). In some embodiments, the period of time in step (d) is between about 0.5 and about 12 hours (e.g., about 0.5, 1, 1.5, 2, 2.5, 3, 3.5, 4, 4.5, 5, 5.5, 6, 6.5, 7, 7.5, 8, 8.5, 9, 9.5, 10, 10.5, 11, 11.5, or about 12 hours).

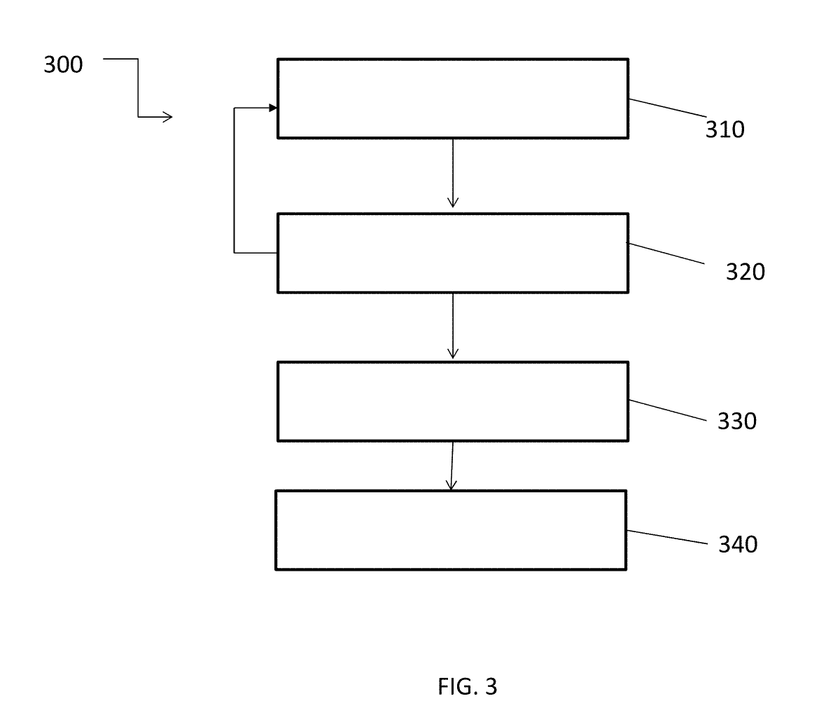

An exemplary embodiment of the method of the presently disclosed subject matter is shown in FIG. 3. In step 310 of method 300 of FIG. 3, a layer of resin mixture comprising a thermoset polymer resin and a pre-determined concentration of nanoparticles is deposited (e.g., in a mold). The pre-determined concentration of nanoparticles can be between about 0 wt % and about 30 wt %. After deposit, the layer of resin mixture is cured in step 320 to provide a thermoset polymer layer having a homogenous dispersion of nanoparticles embedded therein. For example, during the curing of step 320, the deposited layer can be heated to an elevated temperature (e.g., between about 40° C. and about 130° C., such as about 40, 45, 50, 55, 60, 65, 70, 76, 80, 85, 90, 95, 100, 105, 110, 115, 120, 125, or about 130° C.) for a period of time (e.g., between about 10 and about 180 minutes, such as about 10, 20, 30, 40, 50, 60, 70, 80, 90, 100, 110, 120, 130, 140, 150, 160, 170, or about 180 minutes) until the thermoset polymer resin reaches its gel point. The temperature used in step 320 can depend upon the thermoset polymer resin used and the thickness of the layer deposited in step 310. After the layer reaches its gel point, steps 310 and 320 can be repeated one or more times (e.g., 1, 2, 3, 4, 5, 6, 7, 8, 9, or 10 or more times each) until a nanocomposite comprising a plurality of thermoset polymer layers having an total desired thickness has been prepared, each successive layer being deposited and cured upon the top of the previous layer. After the desired overall thickness is reached, the nanocomposite can be cured further in step 330. Then, if desired, one or more face sheet can be laminated to or otherwise applied to one or more sides of the nanocomposite (e.g., to the top and the bottom of the nanocomposite) in step 340, thereby providing a multifunctional structure comprising the nanocomposite.

Any thermoset polymer resin can be used. Suitable thermoset polymer resins include, but are not limited to, polyester, epoxy, phenolic, vinyl ester, cyanate ester, polyurethane, silicone, polyamide, and polyamide-imide resins. In some embodiments, the thermoset polymer is an epoxy resin. Epoxy resins for use according to the presently disclosed subject matter include low molecular weight pre-polymers or higher molecular weight oligomers and polymers. The epoxy resin comprises at least two epoxide groups per molecule, and can be a polyfunctional epoxide having three, four, or more epoxide groups per molecule. In some embodiments, the epoxy resin is liquid at ambient temperature. Suitable epoxy resins include the mono- or poly-glycidyl derivative of one or more of the group of compounds comprising aromatic diamines, aromatic monoprimary amines, aminophenols, polyhydric phenols, polyhydric alcohols, polycarboxylic acids and the like, or a mixture thereof. In some embodiments, the epoxy resin is selected from the group comprising: (i) glycidyl ethers of bisphenol A, bisphenol F, dihydroxydiphenyl sulphone, dihydroxybenzophenone, and dihydroxy diphenyl; (ii) epoxy resins based on Novolacs; and (iii) glycidyl functional reaction products of m- or p-aminophenol, m- or p-phenylene diamine, 2,4-, 2,6- or 3,4-toluoylene diamine, 3,3′- or 4,4′-diaminodiphenyl methane. In some embodiments, the epoxy resin is selected from the diglycidyl ether of bisphenol A (DGEBA); the diglycidyl ether of bisphenol F (DGEBF); O,N,N-triglycidyl-para-aminophenol (TGPAP); O,N,N-triglycidyl-meta-aminophenol (TGMAP); and N,N,N′,N′-tetraglycidyldiaminodiphenyl methane (TGDDM).

The thermoset resin of the presently disclosed subject matter can be thermally curable. The addition of curing agent(s) and/or catalyst(s) to the resin mixture is optional; the use of such can increase the cure rate and/or reduce the cure temperatures, if desired. In some embodiments, one or more curing agent(s) are used, optionally with one or more catalyst(s). In some embodiments, the thermoset resin is thermally cured without the use of curing agents or catalysts.

If used, curing agents suitable for use with epoxy resins, include, but are not limited to, amines (e.g., polyamines and aromatic polyamines), imidazoles, acids, acid anhydrides, phenols, alcohols, and thiols (e.g., polymercaptans). In some embodiments, the curing agent is a polyamine compound selected from the group comprising diethylenetriamine (DETA), triethylenetetramine (TETA), tetraethylenepentamine (TEPA), ethyleneamine, am inoethylpiperazine (AEP), dicyanamide (Dicy), diethyltoluenediamine (DETDA), dipropenediamine (DPDA), diethyleneaminopropylamine (DEAPA), hexamethylenediamine, N-aminoethylpiperazine (N-AEP), menthane diamine (MDA), isophoronediamine (IPDA), m-xylenediamine (m-XDA) and metaphenylene diamine (MPDA). In some embodiments, the amine curing agent is selected from the group including 3,3′- and 4-,4′-diaminodiphenylsulphone (DDS); methylenedianiline; bis(4-amino-3,5-dimethylphenyl)-1,4-diisopropylbenzene; bis(4-aminophenyl)-1,4-diisopropyl-benzene; 4,4′methylenebis-(2,6-diethyl)-aniline (MDEA); 4,4′methylenebis-(3-chloro, 2,6-diethyl)-aniline (MCDEA); 4,4′methylenebis-(2,6-diisopropyl)-aniline (M-DIPA); 4,4′methylenebis-(2-isopropyl-6-methyl)-aniline (M-MIPA); 4-chlorophenyl-N,N-dimethyl-urea; 3,4-dichlorophenyl-N, N-dimethyl-urea, and dicyanodiamide. Bisphenol chain extenders, such as bisphenol-S or thiodiphenol, can also be useful as curing agents for epoxy resins. Suitable curing agents further include anhydrides, particularly polycarboxylic anhydrides, such as nadic anhydride, methylnadic anhydride, phthalic anhydride, tetrahydrophthalic anhydride, hexahydrophthalic anhydride, methyltetrahydrophthalic anhydride, endomethylenetetrahydrophtalic anhydride, or trimellitic anhydride.

In some embodiments, the thermoset resin can include one or more catalyst(s) to accelerate the curing reaction. Suitable catalysts are well known in the art and include Lewis acids or bases. Specific examples include compositions comprising boron trifluoride, such as the etherates or amine adducts thereof (for instance the adduct of boron trifluoride and ethylamine).

In some embodiments, the same resin or combination of resins is used in the resin mixture of each layer. Alternatively, in some embodiments, each layer can be formed from a resin mixture comprising a different resin. In some embodiments, each layer is formed from a resin mixture containing a different resin or resin combination of the same chemical type. For example, in some embodiments, each layer can be prepared from a resin mixture comprising an epoxy resin; however, one or more layer can be formed from a resin mixture comprising a different particular epoxy resin than the epoxy resin used in one of the other layers.

In some embodiments, the nanoparticles are nanoparticles that can absorb and/or disperse radiation. In some embodiments the nanoparticle in each layer comprises one or more of the group comprising boron nanoparticles, boron carbide nanoparticles, gadolinium nanoparticles, nickel nanoparticles, carbon nanotubes, or boron nitride nanotubes. In one variation of any aspect or embodiments, the nanoparticles in each layer have the same chemical composition and/or size. In another variation of any aspect or embodiments, the nanoparticles in each layer have a different chemical composition and/or size. In some embodiments, the nanoparticles in each layer have the same chemical composition, but different sizes. In some embodiments, the nanoparticles in each layer have the same size but different chemical compositions. In some embodiments, the nanoparticles in each layer have the same chemical composition and size. In some embodiments, the nanoparticles in each layer have different chemical compositions and sizes than the nanoparticles in each of the other layers in the nanocomposite.

To prepare the resin mixture, the nanoparticles can be added to the polymer resin (which in some embodiments, can comprise a curing agent and/or catalyst) without any prior dispersion in a liquid carrier and mixed to provide a homogenous mixture. The mixing can be performed using mechanical or ultrasonic means. In some embodiments, the mixing can be performed using a shear mixer. In some embodiments, the mixture can be ultrasonicated. In some embodiments, the resin mixture is free of any additive to improve the compatibility (e.g., the dispersion) of the nanoparticles and the resin. Thus, in some embodiments, the resin mixture is free of any solvent, oil, or surfactant. In some embodiments, the nanoparticles are free of any surface modification and/or chemical modification to make the nanoparticles more compatible with the thermoset polymer resin.

In some embodiments, the separately defined concentration of nanoparticles in each polymer layer is more than 2 wt %, more than 3 wt %, more than 4 wt %, more than 5 wt %, more than 6 wt %, more than 7 wt %, more than 8 wt %, more than 9 wt %, more than 10 wt %, more than 11 wt %, more than 12 wt %, more than 13 wt %, more than 14 wt %, more than 15 wt %, more than 16 wt %, more than 17 wt %, more than 18 wt %, more than 19 wt %, more than 20 wt %, more than 21 wt %, more than 22 wt %, more than 23 wt %, more than 24 wt %, or more than 25 wt %. In some embodiments, the separately defined concentration of nanoparticles in each polymer layer is between about 0 wt % and about 10 wt %, between about 0 wt % and about 15 wt %, between about 0 wt % and about 20 wt % or between about 0 wt % and about 30 wt %. Alternately, in some embodiments, the separately defined concentration of nanoparticles in each polymer layer is each between about 2 wt % and about 10 wt %, between about 2 wt % and about 15 wt %, between about 2 wt % and about 20 wt % or between about 2 wt % and about 30 wt %. Alternately, the separately defined concentration of nanoparticles in each polymer layer is each between about 5 wt % and about 10 wt %, between about 5 wt % and about 15 wt %, between about 5 wt % and about 20 wt % or between about 5 wt % and about 30 wt %.

The methods disclosed herein yield nanocomposites of tailorable thickness comprising at least one region having a high concentration of controllably/uniformly dispersed nanoparticles. In one variation, the high concentration is at least about 5 wt %, at least about 10 wt %, at least about 15 wt %, at least about 20 wt %, at least about 25 wt % or at least about 30 wt %. Thus, in some embodiments, the separately defined concentration of nanoparticles in a least one of the plurality of thermoset polymer layers is about 10 wt % or more. In some embodiments, the separately defined concentration of nanoparticles in at least one of the plurality of thermoset polymer layers is about 15 wt % or more. In some embodiments, the separately defined concentration of nanoparticles in at least one of the plurality of thermoset polymer layers is about 20 wt % or more. In some embodiments, the separately defined concentration of nanoparticles in at least one of the plurality of thermoset polymer layers is between about 10 wt % and about 30 wt %.

In some embodiments, each of the plurality of thermoset polymer layers has the same concentration of nanoparticles homogenously dispersed throughout the layer. Thus, in some embodiments, the concentration of nanoparticles is essentially constant throughout the nanocomposite, as well as being uniform within each layer.

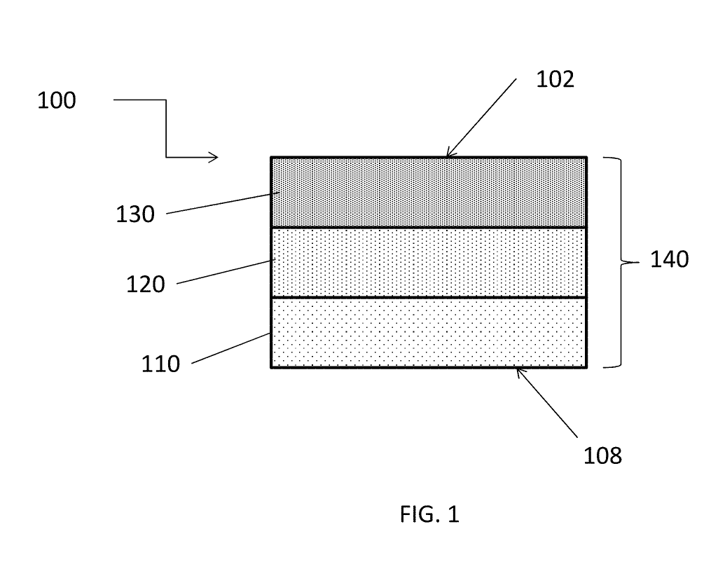

In some embodiments, one or more of the layers can have a different concentration of nanoparticles homogenously dispersed throughout the layer than the concentration homogenously dispersed in one or more of the other layers. In some embodiments, the controlled dispersion of nanoparticles throughout the total nanocomposite provides a controlled nanoparticle concentration gradient. For example, FIG. 1 shows nanocomposite 100 of the presently disclosed subject matter which has total thickness 140 and is formed of three layers. Bottom layer 110 has surface 108 that forms the bottom surface of nanocomposite 100. The other surface of bottom layer 110 is adjacent to middle layer 120. One surface of top layer 130 is adjacent to middle layer 120, while the other surface of top layer 130 forms top surface 102 of nanocomposite 100. By way of exemplification and not limitation, the three layers of nanocomposite 100 each have a different concentration of nanoparticles homogenously dispersed within the layer. Bottom layer 110 has the lowest concentration of nanoparticles (e.g., 5 wt %), middle layer 120 has an intermediate concentration of nanoparticles (e.g., 10 wt %), and top layer 130 has the highest concentration of nanoparticles (e.g., 15 wt %). Thus, in nanocomposite 100, the concentration of nanoparticles increases in a step-wise gradient from the bottom to the top of the nanocomposite. Alternatively, the nanocomposite could be prepared where bottom layer 110 has the highest concentration of nanoparticles and top layer 130 has the lowest concentration of nanoparticles, thereby providing a nanocomposite with a controlled gradient nanoparticle distribution that decreases going from bottom to top.

The chemical composition and/or size of the nanoparticles in each layer can be the same or different. In some embodiments, the presently disclosed methods can yield a nanocomposite with gradient dispersions of combinations of nanoparticles having different sizes and/or properties. In some embodiments, the nanocomposite can comprise layers comprising more than one type of nanoparticles. The more than one type of nanoparticles can be different in chemical composition and/or size from one another. Each type of nanoparticle can be present in a same or different concentration as any other type of nanoparticle in that layer. For example, in some embodiments, each layer can comprise a first type of nanoparticles (e.g., a boron nanoparticle) in a first concentration homogenously dispersed throughout the layer and a second type of nanoparticles (e.g., a gadolinium nanoparticle) in a second concentration homogenously dispersed throughout the layer. In some embodiments, the first and second concentration are the same. In some embodiments, the first and second concentration are different. In some embodiments, the presently disclosed nanocomposite is a hybrid nanocomposite comprising multiple layers each comprising at least two types of nanoparticles, wherein the first nanoparticle is present in the same concentration in each layer and wherein the second nanoparticle has a gradient concentration (i.e., having a concentration that increases or decreases in each adjacent layer).

In some embodiments, each of the plurality of layers is between about 0.1 cm and about 0.4 cm thick (e.g., about 0.1, 0.12, 0.14, 0.16, 0.18, 0.20, 0.22, 0.24, 0.26, 0.28, 0.30, 0.32, 0.34, 0.36, 0.38, or about 0.40 cm thick). In some embodiments, each of the plurality of layers is about 0.35 cm thick or less or about 0.30 cm thick or less. In some embodiments, each of the plurality of layers is about 0.25 cm thick or less.

In some embodiments, the nanocomposite as a whole is between about 0.5 cm and about 10 cm thick (e.g., about 0.5, 1.0, 1.5, 2.0, 2.5, 3.0, 3.5, 4.0, 4.5, 5.0, 5.5, 6.0, 6.5, 7.0, 7.5, 8.0, 8.5, 9.0, 9.5 or about 10 cm thick). In some embodiments, the nanocomposite as a whole is between about 0.75 cm and about 15 cm thick. In some embodiments, the nanocomposite as a whole is between about 1.0 cm and about 20 cm thick. In some embodiments, the nanocomposite as a whole is at least about 0.5 cm thick, at least about 1.0 cm thick, at least about 1.5 cm thick, at least about 2.0 cm thick, at least about 2.5 cm thick, at least about 3.0 cm thick, at least about 3.5 cm thick, at least about 4.0 cm thick, at least about 4.5 cm thick, at least about 5.0 cm thick, at least about 5.5 cm thick, at least about 6.0 cm thick, at least about 6.5 cm thick, at least about 7.0 cm thick, at least about 7.5 cm thick, at least about 8.0 cm thick, at least about 8.5 cm thick, at least about 9.0 cm thick, at least about 9.5 cm thick, or at least about 10.0 cm thick.

In one variation of any aspect or embodiments, the nanocomposite has improved structural strength compared to a nanocomposite of the same thickness and containing the same weight percentage of nanoparticles prepared using a different method, such as by the deposition and curing of a single layer of a thermoset polymer resin mixture comprising nanoparticles. In another variation, the presently disclosed nanocomposite has improved conductivity compared to a nanocomposite of the same thickness and containing the same weight percentage of nanoparticles prepared using a different method. In some embodiments, the conductivity is electrical conductivity and/or thermal conductivity. In one variation, the conductivity is electrical conductivity; in another variation, the conductivity is thermal conductivity.

In some embodiments, the nanocomposite of the present application has a shielding efficiency of at least about 60%, 61%, 62%, 63%, or 64%. In some embodiments, the nanocomposite of the present application has a shielding efficiency of at least about 65%, 66%, 67%, 68%, or 69%. Alternately, in some embodiments, the nanocomposite has a shielding efficiency of at least about 70%, at least about 75%, or at least about 80%. In some embodiments, the nanocomposite is a component part of a multifunctional structure, such as a sandwich panel, which has a shielding efficiency of at least about 99.4%. Alternately, in some embodiments, the multifunctional structure has a shielding efficiency of at least about 99.5%, at least about 99.6%, at least about 99.7%, at least about 99.8%, or at least about 99.9%.

In some embodiments, the presently disclosed subject matter provides a nanocomposite prepared according to a method comprising (a) depositing a layer comprising a resin mixture, wherein the resin mixture comprises a thermoset polymer resin and a pre-determined concentration of nanoparticles; (b) curing the layer until the thermoset polymer resin reaches its gel point, thereby providing a thermoset polymer layer having a homogenous dispersion of nanoparticles of the pre-determined concentration embedded therein; and (c) repeating steps (a) and (b) to provide a nanocomposite comprising a plurality of thermoset polymer layers, wherein each thermoset polymer layer contains a separately defined concentration of nanoparticles, and wherein the nanocomposite has a thickness of at least about 0.5 cm and a controlled dispersion of nanoparticles.

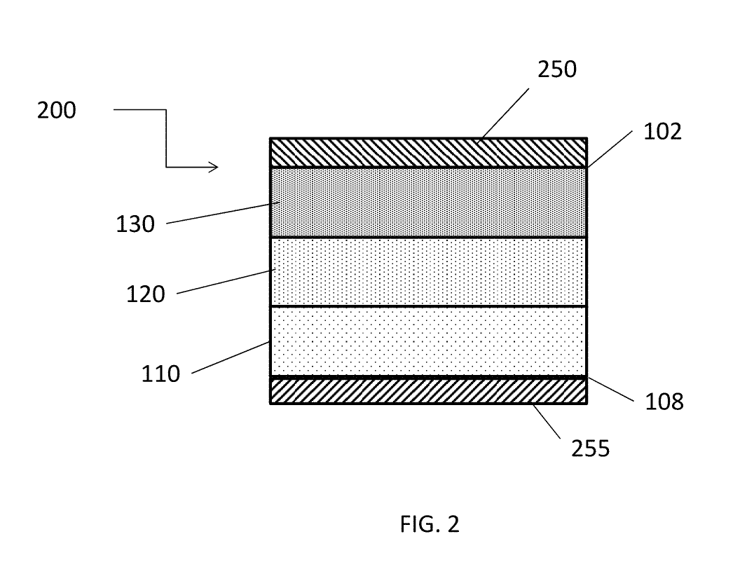

The multifunctional structure can be prepared by affixing one or more face sheets to one or more of the sides of a nanocomposite of the presently disclosed subject matter. In some embodiments, face sheets can be affixed (e.g., laminated or attached via an adhesive) to the bottom and the top surface of the nanocomposite. For example, FIG. 2 shows a multifunctional structure (i.e., sandwich panel) 200 comprising nanocomposite 100 of FIG. 1 (i.e., including bottom layer 110, middle layer 120, and top layer 130 and with top surface 102 and bottom surface 108). In multifunctional structure 200, face sheet 255 has been laminated to bottom surface 108 and face sheet 250 has been laminated to top surface 102. The face sheets can include any suitable material, e.g., metal, synthetic polymer, or natural polymer. In some embodiments, face sheets 250 and 255 can comprise woven polymers. The woven polymer can comprise any polymer that can be spun into fibers. In some embodiments, the woven polymer comprises a polyolefin. In some embodiments, the woven polymer comprises ultrahigh molecular weight polyethylene (UHMWPE) fibers. In some embodiments, the woven polymer comprises a polyester. In some embodiments, the woven polymer comprises aramid fibers, such as, but not limited to the aramid fibers commercially available under the tradename KEVLAR®.

The nanocomposites of the present application can be used in the manufacture of multifunctional structures having both good mechanical and good thermal properties. The structures can be used in particular for radiation shielding, such as shielding against ionizing radiation. Good mechanical properties include, but are not limited to, tensile strength, compressive strength, or flexural strength.

Without being bound by any one theory, when a multifunctional structure comprising a nanocomposite is under a load, any regions of agglomerated or settled nanoparticles are regions of stress concentration, decreasing the mechanical strength, and typically leading to failure of the structure. Sedimentation or agglomeration of nanoparticles within a nanocomposite can additionally introduce voids, which act as preferential sites within the matrix for crack initiation and structural failure. If the nanoparticles are distributed in a controlled manner consistent with the methods disclosed herein, multifunctional structures comprising such nanocomposites do not suffer from such limitations. In addition, in the nanocomposites disclosed herein, conductivity is improved compared to samples not prepared by layer on layer deposition. Such improved conductivity can be observed in thermal, electrical and/or energy absorption/conductivity.

### III. Nanocomposites and Multifunctional Structures

In some embodiments, the presently disclosed subject matter provides a nanocomposite comprising a thermoset polymer matrix and having a thickness of about 0.5 cm or more, wherein the nanocomposite comprises a controlled distribution of nanoparticles throughout the matrix. In some embodiments, the nanocomposite has a thickness of about 0.75 cm, about 1.0 cm, about 1.25 cm, about 1.5 cm, about 2.0 cm, about 2.5 cm, about 3.0 cm, about 3.5 cm, about 4.0 cm, about 4.5 cm, or about 5.0 cm or more. In some embodiments, the nanocomposite is between about 5 cm and about 20 cm (e.g., between about 0.5 cm and about 10 cm, between about 0.75 cm and about 15 cm, between about 1.0 cm and about 20 cm, or between about 5 cm and about 10 cm.

The thermoset polymer matrix can comprise any suitable thermoset polymer, such as, a polyester, an epoxy, a phenolic polymer, a vinyl ester, a cyanate ester, a polyurethane, a silicone, a polyamide, or a polyamide-imide. In some embodiments, the thermoset polymer matrix is an epoxy.

In some embodiments the nanoparticles comprise one or more of the group comprising boron nanoparticles, boron carbide nanoparticles, gadolinium nanoparticles, nickel nanoparticles, carbon nanotubes, or boron nitride nanotubes. In some embodiments, the nanoparticles are free of surface modification and/or chemical derivatization, such as a modification or derivation that could make the nanoparticles more compatible with the polymer matrix and/or the resin cured to provide the polymer matrix. For example, the nanoparticles can be free of any surface coating to make the nanoparticle more hydrophobic and/or any surface coating that is reactive with a group present in the resin. In some embodiments, the resin mixture is free of any additive to improve the compatibility of the nanoparticles and the resin, including, but not limited to, oil, solvent, or surfactant.

In some embodiments, the nanocomposite has a concentration of nanoparticles that is greater than about 5 wt %, greater than about 7.5 wt %, greater than about 10 wt %, greater than about 12.5 wt %, greater than about 15 wt %, greater than about 17.5 wt %, greater than about 20 wt %, or greater than about 25 wt %. In some embodiments, the nanocomposite has a concentration of nanoparticles between about 5 wt % and about 30 wt %. In some embodiments, the nanocomposite has a concentration of nanoparticles between about 10 wt % and about 20 wt %. In some embodiments, the nanocomposite has a concentration of nanoparticles that is about 15 wt %.

In some embodiments, the nanocomposite comprises a plurality of layers (e.g., 2, 3, 4, 5, 6, 7, 8, 9, 10 or more horizontally arranged layers), each of which comprises a homogenous distribution of nanoparticles in a polymer matrix, and wherein the concentration of nanoparticles in at least one layer of the plurality of layers is different from the concentration of nanoparticles in at least one of the other layers. In some embodiments, the concentration of nanoparticles in each of the plurality of layers is different than the concentration of nanoparticles in each of the other layers. In some embodiments, the concentration of nanoparticles in at least one of the layers is greater than about 5 wt %, greater than about 7.5 wt %, greater than about 10 wt %, greater than about 12.5 wt %, greater than about 15 wt %, greater than about 17.5 wt %, greater than about 20 wt %, or greater than about 25 wt %. In some embodiments, at least one layer has a concentration of nanoparticles that is between about 10 wt % and about 30 wt %. In some embodiments, at least one layer has a concentration of nanoparticles that is about 15 wt % or about 20 wt %.

In some embodiments, the concentration, type and/or size of nanoparticles in each of the plurality of layers is different than the concentration, size and/or shape of nanoparticles in each of the other layers. In some embodiments, the nanocomposite comprises at least three layers having the following configuration:
bottom layer/middle layer/top layer
   wherein the bottom layer comprises a first concentration of nanoparticles, the middle layer comprises a second concentration of nanoparticles, and the top layer comprises a third concentration of nanoparticles, and wherein the second concentration of nanoparticles is greater than the first concentration of nanoparticles and lower than the third concentration of nanoparticles, thereby providing a nanocomposite having a gradient distribution of nanoparticles. Alternatively, in some embodiments, the first concentration of nanoparticles is greater than the second concentration of nanoparticles and the second concentration of nanoparticles is greater than the third concentration of nanoparticles. In some embodiments, the nanocomposite can further comprise one or more intermediate layers between the bottom layer and the middle layer and/or between the middle layer and the top layer, wherein each intermediate layer has a nanoparticle concentration that is greater than the concentration of nanoparticles of a layer directly adjacent to one side of said intermediate layer and less than the concentration of nanoparticles of a layer directly adjacent to another side of said intermediate layer, and wherein the concentration of nanoparticles in each of the plurality of layers increases going from one side of the nanocomposite to the other side of the nanocomposite. See also FIG. 1.

In some embodiments, the nanocomposite comprises a plurality of layers, each of which comprises a homogenous dispersion of nanoparticles, and wherein the chemical composition and/or size of the nanoparticles in at least one of the layers is different from the chemical composition and/or size of nanoparticles in at least one of the other layers. In some embodiments, each layer of the nanocomposite can comprise at least two different types of nanoparticles (i.e., nanoparticles of two different chemical compositions and/or sizes). In some embodiments, one type of nanoparticle is present at the same concentration in each of the layers, while a second type of nanoparticle has a different concentration from layer to layer. In some embodiments, the concentration of a first type of nanoparticle is the same from layer to layer, while the concentration of a second type of nanoparticle varies in a controlled gradient from layer to layer.

In some embodiments, the nanocomposite of the present application has a shielding efficiency of at least about 60%, 61%, 62%, 63%, or 64%. In some embodiments, the nanocomposite of the present application has a shielding efficiency of at least about 65%, 66%, 67%, 68%, or 69%. Alternately, in some embodiments, the nanocomposite has a shielding efficiency of at least about 70%, at least about 75%, or at least about 80%.

In some embodiments, the presently disclosed subject matter provides a multifunctional structure comprising the nanocomposite. In some embodiments, the multifunctional structure comprises a sandwich panel. In some embodiments, the sandwich panel comprises at least two face sheets and the nanocomposite, wherein each of the two face sheets is attached (e.g., laminated or otherwise adhered to) to one side of the nanocomposite. In some embodiments, one face sheet is attached to the bottom side of the nanocomposite and a second face sheet is attached to the top side of the nanocomposite. See FIG. 2. In some embodiments, each face sheet comprises a woven polymer, such as a woven polyolefin. In some embodiments, the woven polymer comprises ultrahigh molecular weight polyethylene fibers (UHMWPE). In some embodiments, the woven polymer comprises a polyester. In some embodiments, the woven polymer comprises aramid fibers, including but not limited to the aramid fibers commercially available under the tradename KEVLAR®.

In some embodiments, the multifunctional structure, such as a sandwich panel, has a shielding efficiency of at least about 99.4%. Alternately, in some embodiments, the multifunctional structure has a shielding efficiency of at least about 99.5%, at least about 99.6%, at least about 99.7%, at least about 99.8%, or at least about 99.9%.

In some embodiments, the nanocomposite and/or multifunctional structure can be used to provide radiation shielding building or vehicle components or personal protective equipment. In some embodiments, the components or equipment is for use in the medical, dental or veterinary fields, in the armed forces, in the aeronautical or space exploration field, in a nuclear power facility, or in another type of industrial facility wherein radiation is in use.

### EXAMPLES

The following Examples have been included to provide guidance to one of ordinary skill in the art for practicing representative embodiments of the presently disclosed subject matter. In light of the present disclosure and the general level of skill in the art, those of skill can appreciate that the following Examples are intended to be exemplary only and that numerous changes, modifications, and alterations can be employed without departing from the scope of the presently disclosed subject matter.

### Example 1

### Nanocomposites Containing Boron Nanoparticles

Molds with dimensions of 12 cm×12 cm×1.3 cm (length×width×thickness) were used. EPON™ (Hexion Inc., Columbus, Ohio, United States of America) Resin 862 (an epoxy resin, Diglycidyl Ether of Bisphenol F) and diethyltoluenediamine (EPIKURE™ W), a curing agent, were each obtained from Miller Stephenson Chemical Co. Inc. (Danbury, Conn., United States of America). Boron-Carbide nanoparticles (average diameter 500-700 nm) and boron nanopowder (B, 99.5+%, US research nanomaterial, average diameter 500-600 nm) were each obtained from Electro Abrasive LLC, (Buffalo, N.Y., United States of America). Nickel nanoparticles (90% at ˜70 nm diameter particles) were obtained from US Research Nanomaterials, Inc. (Houston, Tex., United States of America).

Nanocomposites were manufactured using either (1) a simple casting method commonly used in the preparation of epoxy nanocomposites or (2) the method of the present application.

### Preparation of Doped Resin:

Epoxy resin (EPON™ (Hexion, Inc., Columbus, Ohio, United States of America) Resin 862), 154 g, was mixed at room temperature with 40 g curing agent (Diethyltoluenediamine, EPIKURE™ W) at a ratio of 1:0.26. Boron nanoparticles were added to the polymer mixture at loading of 15 weight % (34 g) and dispersed using a reversible shear mixer at 60° C. and then ultra-sonicated (Q125 sonicator, Fisher Scientific, Hampton, N.H., United States of America)

The gel point of a portion of the nanoparticle-doped resin was measured using ASTM D2471 and found to be 104 minutes at 100° C.

The rest of the nanoparticle-doped resin was placed in a vacuum chamber, evacuated to approximately 5 Torr and the mixture was degassed for 45 min at 80° C., reducing the aeration effects from the earlier mixing.

### Method 1—Simple Casting (Comparative Method):

The first mold was filled using a single casting. The mold was placed inside an oven at room temperature, leveled, and the nanoparticle-doped resin was manually cast to achieve a final thickness of about 1.3 cm. Alternately, the nanoparticle-doped resin can be manually cast before the mold is transferred to the oven and leveled.

The resin was cured according to the following cure cycle: raising the oven temperature to 100° C. over 30 mins, then holding at 100° C. for 210 mins (to duplicate the intermediate curing time from Method 2). The oven temperature was then raised to 155° C. and held at that temperature for 3 hours to ensure a complete cure. After the cure, the panel was cooled to room temperature and removed from the oven. The final thickness of the nanocomposite was 1.3 cm.

### Method 2—of the Present Application:

The second mold was filled using the method of the present application. In particular, the mold was filled to one third the thickness of the mold with the doped resin, yielding a layer about 0.43 cm. The mold was placed in the oven, which was heated to 100° C. over 30 minutes, then held at 100° C. for 104 minutes (the gel point/time of the resin, as determined above).

The doped resin to be cast was heated to about 100° C. and a second layer of 0.43 cm thickness was manually deposited on the gelled layer, which was still at about 100° C. The mold was then held in a 100° C. oven for 104 minutes.

The doped resin to be cast was again heated to about 100° C. and a third layer of 0.43 cm thickness was manually deposited in the mold holding the gelled nanocomposite, which was still at about 100° C.

The oven temperature was then raised to 155° C. and held at that temperature for 3 hours to ensure a complete cure of the doped thermoset polymer. After the cure, the panel was cooled to room temperature and removed from the oven. The final thickness was 1.3 cm.

After each nanocomposite panel was removed from the mold, the bottom part of the panels and the top of the panels, relative to the orientation in the mold, were marked.

### Characterization:

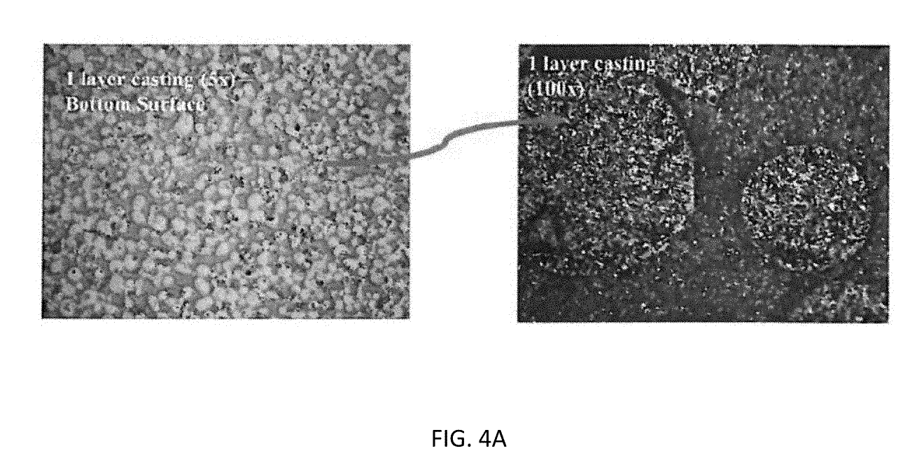

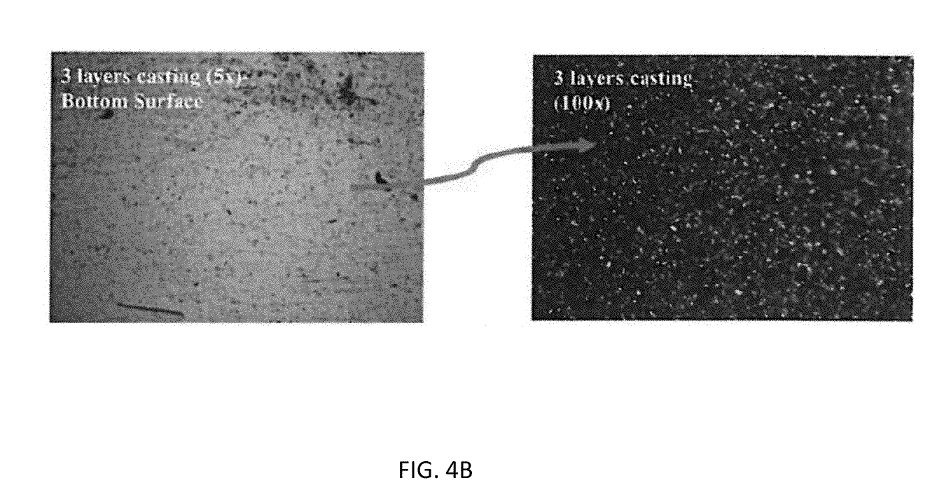

The microstructures of the nanocomposites prepared by Method 1 or Method 2 were obtained using a ZEISS AxioCam MRc 5 optical microscope (Carl Zeiss, Göttingen, Germany). The images (see FIGS. 4A and 4B) show that Method 1 yielded agglomerated nanoparticles, which were not observed in the nanocomposite prepared using Method 2 of the present application. In particular, the bottom surface of nanocomposite prepared by Method 1 show nanoparticles settled out of the resin mixture during the cure and formed agglomerates at the bottom of the composite product. The microstructure of the bottom surface of the mold prepared according to Method 2 with three separately deposited layers did not show the same sedimentation of nanoparticles.

### Volume Density

For the volume density measurements, small samples (typically no more than 0.2 cm deep and about 0.5 cm×0.5 cm) were removed from each of the top side of the nanocomposites and the bottom side of the nanocomposites prepared from each of Method 1 and Method 2.

The volume density of the nanocomposite samples were measured according to ASTM D792. Generally, the steps of the method are: cut a small piece (about 1 gram) from the nanocomposite. The weight of the specimen was measured in air and water. The specific gravity (or relative density) of the sample was calculated using the following equation:

Density=a/(a−b)

where “a” is the weight of specimen without wire or sinker, in air and “b” is weight of specimen immersed in water.

Using the identified volume density of the nanocomposite, measurements according to ASTM D3171 were performed to measure the volume percentage of nanoparticles at the top and the bottom of the samples to evaluate nanoparticle dispersion in the two molds (see Table 1). In these measurements, equivalent portions of the top and bottom of the nanocomposite were cut from each of the panels as described above, weighed, then placed in a furnace and burned at 500° C. for 5 hours, burning off the resin matrix and leaving only the nanoparticles found in each of the 4 samples. Those nanoparticles were then weighed. For each measurement at least three samples were tested.

TABLE 1
Volume percentage calculated for top and bottom of nanocomposites
prepared according to Method 1 and Method 2.

| | Average Vol % of | Standard |
|---|---|---|
| Sample | Nanoparticles | Deviation |
| Epoxy/Boron Nanoparticles, One time | 4.39 | 0.29 |
| casting - Top surface | | |
| Epoxy/Boron Nanoparticles, One time | 6.41 | 0.31 |
| casting - Bottom surface | | |
| Epoxy/Boron Nanoparticles, Layer by | 4.91 | 0.18 |
| Layer casting - Top surface | | |
| Epoxy/Boron Nanoparticles, Layer by | 5.67 | 0.26 |
| Layer casting - Bottom surface | | |

These data show that the volume percentage of nanoparticles contained in the top and bottom surfaces of the nanocomposite manufactured according to Method 2 were almost the same. In the nanocomposite made by Method 1 (simple casting) the nanoparticles had settled—the percentage of nanoparticles measured in the portion taken from the bottom of nanocomposite was greater than the percentage of nanoparticles measured in the portion taken from the top of the nanocomposite.

### Thermal Conductivity

The thermal conductivity of two nanocomposites, each having dimensions of 5 cm×7 cm×1.3 cm, one fabricated using the conventional method (Method 1) and the other fabricated with the disclosed method (Method 2) were tested using Hot Disk (Therm Test Inc., Fredericton, New Brunswick, Canada).

According to the procedure using a transiently heated plane sensor the following steps were followed: A plane Hot Disk sensor, made of a continuous double spiral of nickel metal covered with a thin layer of polyimide film, was placed between two samples of nanocomposite prepared according to Method 1, such that the “tops” of each sample were facing each other and in contact with the sensor. The sensor is a heat source and a temperature monitor: by running a small electrical current through the sensor, the temperature increases in the sensor. Depending on the thermal conductivity properties of the samples on both sides of the sensor, the generated heat dissipates into the sample in different rates. The temperature vs time response in the sensor is recorded and the thermal conductivity of material is calculated from those data.

The same process was followed to measure the thermal conductivity of the “bottom” surfaces of the nanocomposite prepared according to Method 1, except that the ‘bottom’ of two nanocomposites were held in contact with one another and with the sensor.

The process was followed to measure the thermal conductivity of each of the top surface and the bottom surface of the nanocomposite prepared according to Method 2.

As shown in Table 2, the thermal conductivity values obtained for the top and bottom surfaces of the Method 2 nanocomposite are close (0.3277±0.005 Watts per meter-Kelvin (W/m K) and 0.3208±0.005 W/m K), whereas the values obtained for the sample fabricated with the conventional method are more disparate (0.2825±0.009 W/m K and 0.3987±0.010 W/m K).

The similarity of the thermal conductivities measured for the nanocomposite prepared according to the methods of the present application are consistent with the top and bottom layers having a similar weight percentage of nanoparticles, while disparate measured thermal conductivities of the conventionally cast nanocomposite top and bottom layers are consistent with the presence of more nanoparticles in the bottom surface compared to the top surface. In particular, the higher thermal conductivity of the bottom surface of the conventionally cast nanocomposite is consistent with sedimentation of the nanoparticles.

TABLE 2
Thermal conductivity measured for top and bottom of nanocomposites
prepared according to Method 1 and Method 2.

| | Thermal Conductivity | Standard Deviation |
|---|---|---|
| Sample | (W/m K) | (W/m K) |
| Epoxy/Boron | 0.2825 | 0.009 |
| Nanoparticles, One time | | |
| casting - Top surface | | |
| Epoxy/Boron | 0.3987 | 0.010 |
| Nanoparticles, One time | | |
| casting - Bottom surface | | |
| Epoxy/Boron | 0.3208 | 0.005 |
| Nanoparticles, Layer by | | |
| Layer casting - Top | | |
| surface | | |
| Epoxy/Boron | 0.3277 | 0.005 |
| Nanoparticles, Layer by | | |
| Layer casting - Bottom | | |
| surface | | |

### Flexural Strength

Two nanocomposite panels each comprising 15 wt % of boron nanopowder were fabricated with dimensions of 30 cm×30 cm×1.3 cm, one based on Method 1 and other based on Method 2. From each panel, 10 specimens with dimensions of 28 cm×2 cm×1.3 cm were cut using water jet cutter. The flexural strength of the nanocomposites was measured by Four Points Bending Test based on ASTM D6272 using an Instron 3384 and Instron manual grips (Instron, Norwood, Mass., United States of America). For each sample, five specimens were tested while the bending load was applied to the top surface and five specimens were tested when the bending load was applied to the bottom surface. Based on the resulting load-deflection curve, the flexural stress, e.g. the maximum stress in each specimen before the failure, was calculated using the following equation:

$$Stress = \frac{3 \cdot P \cdot L}{4 \cdot {bd}^{2}}$$

where P is applied force, L is support span, b is width of beam, and d is thickness of beam. Table 3 shows the average flexural strength data for samples, where the flexural strength of the top and bottom surface of the layer casting (Method 2) nanocomposite were closer than the one-time casting (Method 1).

TABLE 3
Average flexural strength for top and bottom of nanocomposites
prepared according to Method 1 (one-time casting) and Method 2
(layer casting).

| | Flexural Strength | Standard Deviation |
|---|---|---|
| Sample | (MPa) | (MPa) |
| Epoxy/Boron Nanoparticles, | 64 | 1.9 |
| One time casting - Top surface | | |
| Epoxy/Boron Nanoparticles, | 118 | 9.4 |
| One time casting - Bottom | | |
| surface | | |
| Epoxy/Boron Nanoparticles, | 74 | 1.7 |
| Layer by Layer casting - Top | | |
| surface | | |
| Epoxy/Boron Nanoparticles, | 88 | 3.1 |
| Layer by Layer casting - | | |
| Bottom surface | | |

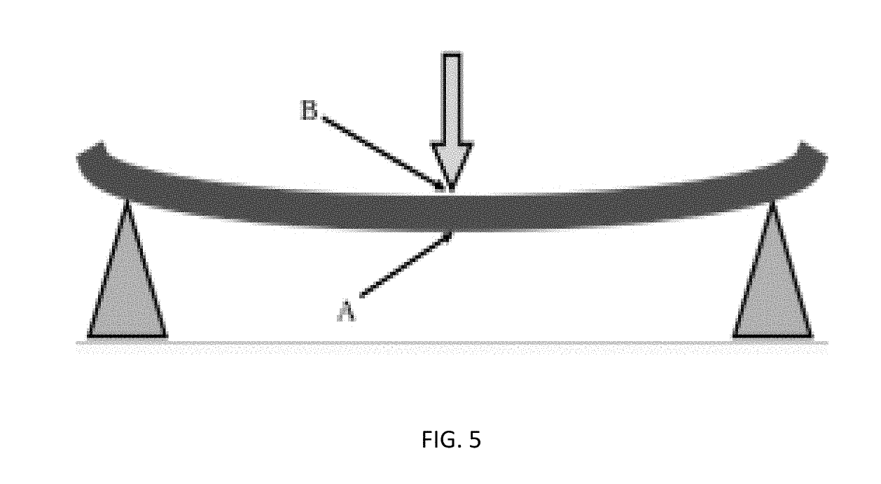

Without being bound by theory, it is believed that when under compression, the negative effects due to defects caused by agglomeration of nanoparticles are minimized, because the defects, e.g. cracks, are ‘closed’ under compression (when the bottom surface of the one-time casting sample is under measurement, point B in FIG. 5). When the top surface of the one-time casting is under measurement, the defects, e.g. cracks, due to the agglomeration of nanoparticles are exacerbated by the bending (point A in FIG. 5). The narrower range of flexural strength for the top and bottom surfaces of the layer by layer casting (Method 2), correspond to the substantially homogenous distribution of nanoparticles in the top and bottom surfaces.

### Neutron Absorption

The neutron absorption of materials can be theoretically obtained using the following equation:

$$\frac{{I}_{t}}{{I}_{0}} = {e}^{Σ t}$$

where, (I₍ₜ₎/I₀) is the decrease in the neutron flux, Σ (cm⁻¹) is the total macroscopic thermal neutron absorption cross-section and t is the thickness of medium. The total macroscopic neutron cross-section (Σ) in a composite is the sum of microscopic neutron cross-section of each component in the composite multiple by its atomic density:

$$Σ {cm}^{- 1} = {\sum }_{i}^{n} Microscopic neutron crosssection \frac{{cm}^{2}}{atom} \times atomic density \frac{atom}{{cm}^{3}}$$

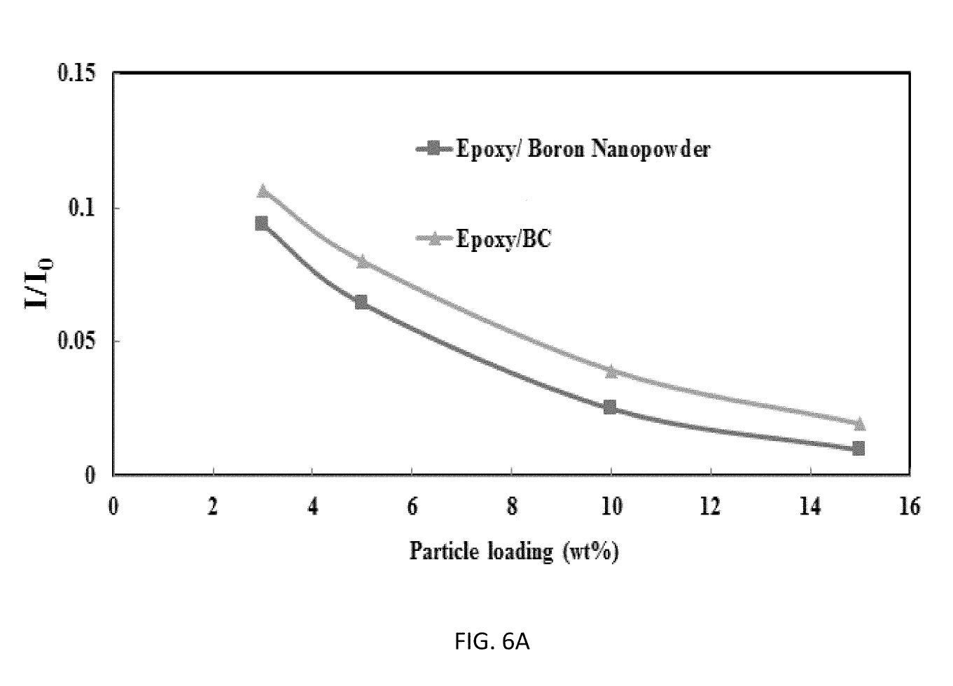

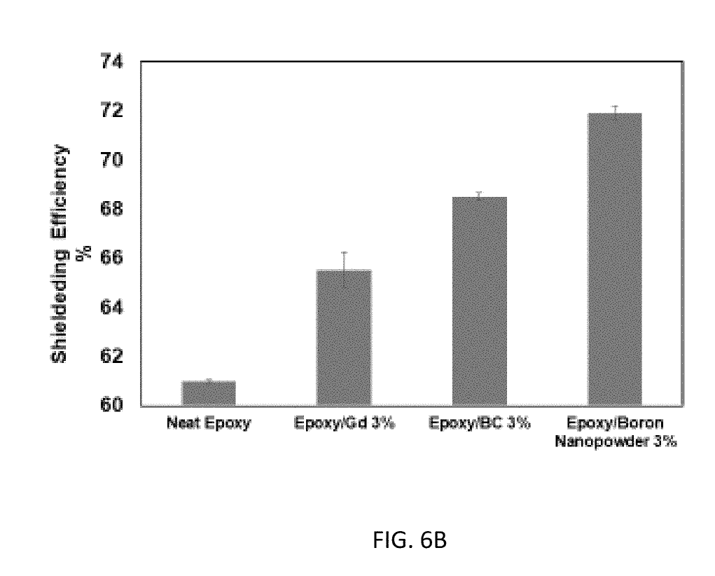

FIG. 6A is a graph of the theoretical neutron absorption by nanocomposites as a function of particle loading, as exemplified by epoxy with boron nitride nanoparticles or epoxy with boron nanopowder.

### Shielding Efficiency

The shielding efficiency of the nanocomposites of the present application was measured using the Breazeale Nuclear Reactor (State College, Pa., United States of America) as the neutron source. Neutrons from the Breazeale reactor are thermalized (energy ˜0.025 eV) and collimated into three neutron beams and enter the neutron transmission attenuation testing system. The transmission system measures the number of neutrons transmitted through sample materials. The neutron attenuation was measured using one or two independent counting systems, each consisting of a BF₃ neutron detector. Since reactor flux is not constant, precision is improved by monitoring the incident neutron beam and normalizing the test counts and subtracting system background counts.

Nanocomposites of the present application, prepared as described herein and containing gadolinium, or boron carbide nanoparticles or boron nanoparticles, showed effective shielding efficiency, particularly compared to neat epoxy. See FIG. 6B. When used in the manufacture of a sandwich structure, using methods known to those of skill in the art, the resulting multifunctional structure shows improved shielding efficiency.

### Example 2

### Nanocomposites Containing Boron Carbide

Following the preparative methods of Example 1, two nanocomposites were manufactured from a resin mix containing 154 g Epoxy resin (EPON™ (Hexion, Inc., Columbus, Ohio, United States of America) Resin 862), 40 g curing agent (Diethyltoluenediamine, EPIKURE W) and boron carbide was added to the polymer mixture at loading of 15 weight % using each of Method 1 and Method 2 (the method of the present application).

The nanocomposite prepared according to Method 2 showed lower agglomeration/sedimentation of nanoparticles compared to the nanocomposite prepared according to Method 1. Correspondingly, the nanocomposite prepared according to Method 2 had better structural integrity and conductivity.

### Example 3

### Nanocomposites Containing Carbon Nanotubes

Following the preparative methods of Example 1, two nanocomposites are manufactured from a resin mix containing 154 g Epoxy resin (EPON™ (Hexion, Inc., Columbus, Ohio, United States of America) Resin 862), 40 g curing agent (Diethyltoluenediamine, EPIKURE W) and carbon nanotubes (e.g. XD-CNTs (conductive grade carbon nanotube), Unidym (Houston, Tex., United States of America); which is a mixture of single walled, double walled, multi-walled nanotubes along with carbon black and metallic impurities) are added to the polymer mixture at loading of 15 weight % using Method 1 and Method 2.

The nanocomposite prepared according to Method 2 will show lower agglomeration/sedimentation of nanoparticles compared to the nanocomposite prepared according to Method 1. Correspondingly, the nanocomposite prepared according to Method 2 will have better structural integrity and conductivity.

### Example 4A

### Nanocomposites Containing 15% Boron Nitride Nanoparticles

Following the preparative methods of Example 1, two nanocomposites were manufactured from a resin mix containing 154 g Epoxy resin (EPON™ (Hexion, Inc., Columbus, Ohio, United States of America) Resin 862), 40 g curing agent (Diethyltoluenediamine, EPIKURE W) and 34 g boron nitride nanoparticles (e.g. ˜800 nm average diameter, US Research Nanomaterials, Inc. (Houston, Tex., United States of America) at loading of 15 weight % using Method and Method 2.

The nanocomposite prepared according to Method 2 lowered agglomeration/sedimentation of nanoparticles compared to the nanocomposite prepared according to Method 1. Correspondingly, the nanocomposite prepared according to Method 2 had better structural integrity and conductivity.

### Example 4B

### Nanocomposites Containing 20% Boron Nitride Nanoparticles

Following the preparative methods of Example 4A, two nanocomposites were manufactured with 20 weight % boron nitride nanoparticles using each of Method 1 and Method 2.

The nanocomposite prepared according to Method 2 showed lower agglomeration/sedimentation of nanoparticles compared to the nanocomposite prepared according to Method 1 and additionally had better properties.

### Example 5

### Nanocomposites with Nanoparticle Gradient

### Preparation of Doped Resins:

Epoxy resin (EPON™ (Hexion, Inc., Columbus, Ohio, United States of America) Resin 862), 154 g, is mixed at room temperature with 40 g curing agent (Diethyltoluenediamine, EPIKURE W) at a ratio of 1:0.26 and the resin mix is divided into four samples. Nanoparticles are added to the polymer mixtures at loading of 2 wt %, 3 wt %, 10 wt %; the fourth resin mix does not have any nanoparticles added. The mixtures were dispersed using a reversible shear mixer at 60° C. and then ultra-sonicated (Q125 sonicator, Fischer Scientific, Hampton, N.H., United States of America)

The gel point of a portion of each nanoparticle-doped resin is measured using ASTM D2471, consistent with the method outlined above.

The resin samples are placed in a vacuum chamber, evacuated to approximately 5 Torr and degassed for 45 min at 80° C. to reduce the effects of the aeration due to the earlier mixing.

### Method of the Present Application:

A mold of 1.3 cm depth is filled to one fourth the thickness (0.325 cm) with the resin sample containing 0 wt % nanoparticle. The mold is placed in the oven, which is heated to the gel point/time of the resin, as determined above.

The resin sample containing 2 wt % nanoparticle is heated to the measured gel temperature and a layer of ˜0.325 cm thickness is manually deposited on the gelled layer, which itself is held at the measured gel temperature. The mold is then held at the gel point/time of the resin, as determined above.

The resin sample containing 3 wt % nanoparticle is heated to about the measured gel temperature and a layer of ˜0.325 cm thickness is manually deposited on the gelled sample, which itself is held at the measured gel temperature. The mold is then held at the gel point/time of the resin, as determined above.

The resin sample containing 10 wt % nanoparticle is heated to about the measured gel temperature and a layer of ˜0.325 cm thickness is manually deposited on the gelled sample, which itself is held at the gel point/time of the resin, as determined above.

The oven temperature is then raised to a curing temperature and held at that temperature for time to ensure a complete cure of the thermoset polymer containing a controlled gradient concentration of nanoparticles. After the cure, the panel is cooled to room temperature and removed from the oven. The final thickness is 1.3 cm.

The nanocomposite having a controlled gradient of boron nitride nanoparticles demonstrates limited agglomeration/sedimentation of nanoparticles and good structural integrity and conductivity.

The disclosed method has been shown to be effective at decreasing nanoparticle sedimentation and improving dispersion of nanoparticles throughout the thickness of the nanocomposite.

### Example 6

### Multifunctional Structure Comprising Nanocomposites

Multifunctional sandwich panels were manufactured using Heat-Vacuum Assisted Resin Transfer Molding method (H-VAR™, a method generally disclosed in U.S. Pat. No. 9,114,576, the disclosure of which is incorporated herein by reference in its entirety. Briefly, the method includes forming a sandwich composite according to the following steps:

1. Mold preparation and fabric lay-up.

2. Sealing the mold and creating a vacuum.

3. Resin preparation and degassing.

4. Resin impregnation.

5. Cure cycle of fabricated panels.

In each sandwich panel the core sheet is separated two face sheets and each face sheet consists of 6 layers of UHMWPE mats.

In this process, the heating pads were placed under a glass mold to thoroughly cover the entire mold. A piece of fiberglass insulation was placed between the tabletop and the heating pad. A layer of release agent was applied to the surface for easy release of the composite panel. Next the bottom release fabric, which leaves an impression on the part suitable for secondary adhesive bonding (like tabbing) without further surface preparation, was laid down. Six plies of UHMWPE having similar dimensions were cut for each face sheet and placed at the top and bottom of core sheet. Another peel ply was placed on the top of the stacked sequence of fabric, enabling easy removal of the composite panel after fabrication from the vacuum bag. This porous release material facilitates the resin flow through and leaves an impression on the part suitable for secondary bonding without further surface preparation.

Then the distribution medium was laid on top of the top release fabric. A PE Spiral Wire Wrap tube was used as the resin distribution tube and extended approximately 2″ over the longest edge of the stacked layers. Another tube of similar dimensions was used as the vacuum line. These lines were laid above the distribution media at the two edges along the length of the stacked fabric lay-up. The resin line was closed at one end and connected to the resin supply through the peristaltic pump at the other end. The vacuum line was closed at one end and connected to a vacuum pump through the vacuum gage. It is standard practice to place the closed ends of these lines in opposite directions to each other.

Nylon bagging film was used as the vacuum bag and placed over the mold area and sealed firmly using an extruded sealing compound. The resin was degassed and injected into the mold at a very slow rate till the whole panel was soaked into resin. Then the cure cycle was performed on each composite panel.

The shielding efficiencies of three sandwich panels comprising a nanocomposite of the presently disclosed subject matter and prepared according to the H-VAR™ method were tested. A panel comprising a nanocomposite comprising epoxy with 3% gadolinium nanoparticles had a shielding efficiency of 99.4%; a panel comprising a nanocomposite comprising epoxy with 3% boron carbide nanoparticles had a shielding efficiency of 99.5%; and a panel comprising a nanocomposite comprising epoxy with 3% boron nanopowder had a shielding efficiency of between 99.6% and 99.7%.

It will be understood that various details of the presently disclosed subject matter may be changed without departing from the scope of the presently disclosed subject matter. Furthermore, the foregoing description is for the purpose of illustration only, and not for the purpose of limitation.

What is claimed is:

1. A method of preparing a nanocomposite comprising:
(a) depositing a layer comprising a resin mixture, wherein the resin mixture comprises a thermoset polymer resin and a pre-determined concentration of nanoparticles;
(b) curing the layer until the thermoset polymer resin reaches its gel point, thereby providing a thermoset polymer layer having a homogenous distribution of nanoparticles of the pre-determined concentration embedded therein; and
(c) repeating the deposition/curing steps (a) and (b) to provide a nanocomposite comprising a plurality of thermoset polymer layers, wherein each thermoset polymer layer contains a separately defined concentration of nanoparticles, and wherein the nanocomposite has a thickness of at least about 0.5 centimeters (cm) and a controlled dispersion of nanoparticles.

2. The method of claim 1, wherein the thermoset polymer resin is an epoxy resin.

3. The method of claim 1, wherein the nanoparticles in each thermoset polymer layer are independently selected from the group consisting of boron nanoparticles, boron carbide nanoparticles, gadolinium nanoparticles, nickel nanoparticles, carbon nanotubes, and boron nitride nanotubes.

4. The method of claim 1, wherein the nanoparticles in each of the plurality of thermoset polymer layers have the same chemical composition and/or the same size.

5. The method of claim 1, wherein the nanoparticles in each of the plurality of thermoset polymer layers have a different chemical composition and/or a different size.

6. The method of claim 1, wherein the separately defined concentration of nanoparticles in at least one of the plurality of thermoset polymer layers is more than about 10 weight percent (wt %).

7. The method of claim 1, wherein the separately defined concentration of nanoparticles in each of the plurality of thermoset polymer layers is between about 2 wt % and about 10 wt %.

8. The method of claim 1, wherein the nanocomposite is at least about 1.0 cm thick.

9. The method of claim 1, wherein said nanocomposite has improved structural strength compared to a nanocomposite of the same thickness and containing the same weight percentage of nanoparticles prepared using a different method, optionally wherein the different method comprises depositing and curing a single layer of a mixture comprising a thermoset polymer resin and nanoparticles.

10. The method of claim 1, wherein said nanocomposite has improved conductivity compared to a nanocomposite of the same thickness and containing the same weight percentage of nanoparticles prepared using a different method, optionally wherein the different method comprises depositing and curing a single layer of a mixture comprising a thermoset polymer resin and nanoparticles.

11. The method of claim 10, wherein said improved conductivity is an electrical conductivity and/or a thermal conductivity.

12. The method of claim 1, wherein the nanocomposite has a shielding efficiency of at least about 65%.

13. The method of claim 1, wherein the resin mixture is free of an additive to improve the compatibility of the nanoparticles and the resin.

14. The method of claim 1, wherein the nanoparticles are free of surface modification and/or chemical derivatization.

15. The nanocomposite produced by the method of claim 1.

16. A multifunctional structure comprising a nanocomposite of claim 15, optionally wherein said multifunctional structure comprises a sandwich panel comprising two face sheets and the nanocomposite, wherein each of the two face sheets is laminated to one side of the nanocomposite.

17. A nanocomposite comprising a thermoset polymer matrix and having a thickness of about 0.5 centimeter of more, wherein the nanocomposite comprises a controlled dispersion of nanoparticles distributed throughout the matrix.

18. The nanocomposite of claim 17, having a thickness of about 1.0 cm or more.

19. The nanocomposite of claim 17, wherein the nanocomposite has a concentration of nanoparticles of greater than about 10 wt %.

20. The nanocomposite of claim 17, wherein the nanoparticles are independently selected from the group consisting of boron nanoparticles, boron carbide nanoparticles, gadolinium nanoparticles, nickel nanoparticles, carbon nanotubes, and boron nitride nanotubes.

21. The nanocomposite of claim 20, wherein the nanoparticles are free of surface modification and/or chemical derivatization.

22. The nanocomposite of claim 17, wherein the nanocomposite comprises a plurality of layers, each of which comprises a homogenous distribution of nanoparticles and wherein the concentration of nanoparticles in at least one layer is different from the concentration of nanoparticles in at least one of the other layers.

23. The nanocomposite of claim 17, wherein the nanocomposite comprises a plurality of layers, each of which comprises a homogenous dispersion of nanoparticles, and wherein the chemical composition and/or size of the nanoparticles in at least one of the layers is different from the chemical composition and/or size of nanoparticles in at least one of the other layers.

24. A multifunctional structure comprising the nanocomposite of claim 17.

25. The multifunctional structure of claim 24, wherein the multifunctional structure comprises a sandwich panel, wherein said sandwich panel comprises two face sheets and the nanocomposite, and wherein each of the two face sheets is laminated to one side of the nanocomposite, wherein each of the two face sheets comprises a woven polymer, optionally wherein the woven polymer comprises ultrahigh molecular weight polyethylene fibers (UHMWPE).
